(19) United States
(12) Patent Application Publication
(10) Pub. No.: US 2025/0257455 A1
(43) Pub. Date: Aug. 14, 2025

(54) REMOTE DOPING OF A SEMICONDUCTOR STRUCTURE, RELATED DEVICES, RELATED SYSTEMS, AND RELATED METHODS

(71) Applicant: ASM IP Holding B.V., Almere (NL)

(72) Inventors: Alessandra Leonhardt, Sipoo (FI); Vivek Koladi Mootheri, Leuven (BE); Gaurav Pathak, Chandler, AZ (US); Michael Eugene Givens, Scottsdale, AZ (US)

(21) Appl. No.: 19/047,098

(22) Filed: Feb. 6, 2025

Related U.S. Application Data
(60) Provisional application No. 63/551,711, filed on Feb. 9, 2024.

(51) Int. Cl. C23C 16/455; C23C 16/34; H01L 21/02; H01L 21/225; H10D 62/80

(52) U.S. Cl. CPC C23C 16/45527; C23C 16/34; H01L 21/0262; H01L 21/225; H10D 62/882; H10D 62/883

(57) ABSTRACT

The technology of the present disclosure generally relates to the field of semiconductor devices. More particularly, it relates to a field-effect transistor (FET) and systems and methods for producing the same. The FET comprising: a substrate; at least one channel layer comprising a channel material; a source electrode and a drain electrode in electrical contact with the channel layer; at least one gate electrode in contact with a gate insulating layer; at least one remote dopant layer in electrical contact with at least a portion of the gate electrode or the gate insulating layer; wherein the remote dopant layer comprises at least one boron-containing material; and wherein the remote dopant layer is configured for remote doping of the channel material of the channel layer.

### CROSS-REFERENCE TO RELATED APPLICATION(S)

This application claims the benefit of U.S. Provisional Application 63/551,711 filed on Feb. 9, 2024, the entire contents of which are incorporated herein by reference.

### FIELD

The present disclosure generally relates to the field of semiconductor devices. More particularly, it relates to field-effect transistors comprising at least one remote dopant layer, which comprises at least one boron compound, and methods and systems for producing the same.

### BACKGROUND OF THE DISCLOSURE

Field-effect transistors (FETs) are widely known electronic devices used to control the flow of electrical current in a circuit. Conventional transistors are typically using various semiconductor material, such as silicon, which involve thicker layers. However, with the increased miniaturization of electronic devices, there is a growing demand for transistors with novel materials and thinner designs suitable for the demands of modern electronic devices.

In recent years, there has been significant interest in using two-dimensional (2D) materials, such as graphene or transition metal dichalcogenides (TMDCs), as the channel material of FETs due to their unique electronic properties. For instance, 2D material-based channels are particularly interesting for precisely controlling the flow of electrical current between a source electrode and a drain electrode through modulation of the voltage/field of a gate electrode.

However, due to the intrinsic atomic thickness of 2D materials, one of the major remaining challenges is to achieve precise doping at specific regions of the channel to control its electrical properties. Common doping techniques such as ion implantation, chemical treatments, co-deposition, and oxide top layers all result in poor local control, material degradation, and decreased thermal stability. Moreover, achieving both p- and n-doping with the same material is challenging using traditional doping techniques.

Hence, there is a need to address the aforementioned challenges of current doping technology for 2D materials to obtain improved transistors. In particular, without compromising the transistor's high stability and threshold voltage. This is advantageous for the development of commercially relevant and reliable FETs.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In general, the technology disclosed herein relates to the field of semiconductor devices, and more particularly to the “remote doping” of semiconductor devices. Remote doping as used herein refers to the introduction of dopants (e.g., a boron compound) into a region of a semiconductor that is physically separated from another region requiring doping. Such remotely doped devices may improve the electrical performance of field-effect transistors (FET) s, while retaining the basic FET capability to switch between “on” and “off” states in response to a gate voltage or field.

Accordingly, in some broad aspects, the present disclosure relates to FETs, and methods and systems for manufacturing at least a part of said FETs. These FETs can be suitable as electronic components for various applications such as central processing units (CPU) s and system-on-a-chip (SoC). An aspect of the present disclosure relates to a field-effect transistor (FET) comprising: a substrate, at least one channel layer comprising a channel material, optionally, at least one insulating layer, a source electrode and a drain electrode in electrical contact with the channel layer, at least one gate electrode in contact with a gate insulating layer, at least one remote dopant layer in electrical contact with at least a portion of the gate electrode or the gate insulating layer, wherein the remote dopant layer comprises at least one boron-containing material, and wherein the remote dopant layer is configured for remote doping of the channel material of the channel layer.

It should be appreciated that, although the use of remote dopant layers to induce doping has previously been considered using defective oxide layers, such oxide layers do not deliver the desired local doping with high efficiency and reduced defects. Hence, compromising the stability and integrity of the FET. This is in contrast to the present disclosure, where a remote dopant layer, as disclosed herein, can provide both controlled and local doping of specific regions of the channel layer comprising the channel material. Without being bound by any particular theory or mode of operation, it is believed that charged defect states create a net charge in the remote dopant layer. This net charge creates an electric field which causes band bending in the channel material, thereby controlling band alignment in the channel region without having to rely on in-situ doping. Moreover, said remote dopant layer may be configured to provide both p-doping and n-doping, thereby overcoming several challenges of the state of the art.

Another advantage is that the present FETs may be configured in various ways resulting in, for instance, a single gate or multiple gate structure, which increases the flexibility in FET manufacturing. Non-limiting examples of such FET configurations are further described herein below.

In a particular embodiment, the FET as disclosed herein provides that the boron-containing material may be selected from the group consisting of boron nitride (BN), boron carbide (BC), boron carbon nitride (BCN), and mixtures thereof.

An overview of various other aspects of the technology of the present disclosure is provided herein below, followed by a detailed description of specific embodiments. It should be understood that the objectives and advantages mentioned above apply equally to the various other aspects and features as disclosed herein.

Another aspect of the present disclosure relates to a method for the manufacturing of at least a portion of a FET, comprising the steps of: providing a substrate into a reaction chamber, executing one or more cycles, a cycle comprising a boron precursor pulse, wherein at least a part of the substrate is contacted with at least one boron precursors by introducing the boron precursor into the reaction chamber, wherein, as a result of the cycles, at least one remote dopant layer comprising a boron-containing material is formed on the substrate; wherein the substrate comprises at least one channel layer comprising a channel material that is formed before or after the forming of the remote dopant layer, or a combination thereof; wherein the at least one remote dopant layer is configured for the remote doping of the channel material of the channel layer during operation of the FET.

In other words, the method as disclosed herein generally relates to a deposition process, wherein the remote dopant layer may be gradually grown as a thin-film during one or more cycles. This may provide the advantage that the remote dopant layer can be formed with a controlled thickness, reduced defects, and high flexibility in composition. Hence, resulting in a more reliable doping of local regions in the channel layer.

In a particular embodiment, the method as disclosed herein provides that the at least one channel layer may be formed by: providing the substrate to the reaction chamber, executing one or more cycles, a cycle comprising a transition metal precursor pulse, wherein at least a part of the substrate is contacted with at least one transition metal precursor by introducing the transition metal precursor into the reaction chamber, a chalcogenide reactant pulse, wherein at least a part of the substrate is contacted with at least one chalcogenide reactant by introducing the chalcogenide reactant into the reaction chamber, wherein, as a result of the cycles, at least one channel layer comprising a channel material is formed on at least one of the substrate and the remote dopant layer.

Another aspect of the present disclosure relates to a system for the manufacturing of at least a portion of a field-effect transistor comprising: a reaction chamber constructed and arranged to hold a substrate, a boron precursor vessel constructed and arranged to contain and evaporate at least one boron precursor, optionally, a reactant gas vessel and a plasma power source, a transition metal precursor vessel constructed and arranged to contain and evaporate at least one transition metal precursor, a chalcogenide reactant vessel constructed and arranged to contain and evaporate at least one chalcogenide reactant, a controller, operatively connected to the boron precursor vessel, the transition metal precursor vessel, and the chalcogenide reactant vessel, wherein the controller is configured to control the introduction of the boron precursor, the transition metal precursor, and the chalcogenide reactant into the reaction chamber during one or more cycles, wherein, as a result of the cycles, at least one remote dopant layer comprising a boron compound and at least one channel layer comprising a channel material are formed on the substrate; and wherein the remote dopant layer is configured for remote doping of the channel material comprised in the channel layer during operation of the field-effect transistor.

In a particular embodiment, the system as disclosed herein is configured to manufacture a FET as disclosed herein.

In a particular embodiment, the system as disclosed herein is configured to form at least a portion of a FET by means of a method as disclosed herein.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 schematically illustrates an exemplary embodiment of a single gate field-effect transistor (100) as disclosed herein.

FIG. 2 schematically illustrates another exemplary embodiment of a single gate field-effect transistor (200) as disclosed herein.

FIG. 3 schematically illustrates another exemplary embodiment of a single gate field-effect transistor (300) as disclosed herein.

FIG. 4 schematically illustrates an exemplary embodiment of a double gate field-effect transistor (400) as disclosed herein.

FIG. 5 schematically illustrates another exemplary embodiment of a double gate field-effect transistor (500) as disclosed herein.

FIG. 6 schematically illustrates another exemplary embodiment of a double gate field-effect transistor (600) as disclosed herein.

FIG. 7 schematically illustrates an exemplary embodiment of a three-dimensional (3D) gate field-effect transistor (700) as disclosed herein.

FIG. 8 schematically illustrates another exemplary embodiment of a three-dimensional (3D) gate field-effect transistor (800) as disclosed herein.

FIG. 9 schematically illustrates another exemplary embodiment of a three-dimensional (3D) gate field-effect transistor (900) as disclosed herein.

FIG. 10 schematically illustrates an exemplary embodiment of a method for the manufacturing of at least a portion of a field-effect transistor as disclosed herein.

FIG. 11 schematically illustrates another exemplary embodiment of a method for the manufacturing of at least a portion of a field-effect transistor as disclosed herein.

FIG. 12 schematically illustrates an exemplary embodiment of a system (1200) for the manufacturing of at least a portion of a field-effect transistor as disclosed herein.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure. Hence, the description below is to be regarded as illustrative in nature, and not as restrictive.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements, or method steps. The terms “comprising”, “comprises” and “comprised of” when referring to recited members, elements or method steps also include embodiments which “consist of” the recited members, elements, or method steps. The singular forms “a”, “an”, and “the” include both singular and plural referents unless the context clearly dictates otherwise.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

In this disclosure, “high-k dielectric” refers to a dielectric material with a high relative permittivity. This type of dielectric is characterized by its ability to store electrical energy efficiently, making it particularly valuable for applications in electronic devices. A high-k dielectric can include materials that exhibit a high dielectric constant compared to traditional dielectrics like silicon dioxide. Depending on the specific application, the high-k dielectric may comprise a single material or a combination of materials, compounds or alloys as known in the art.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

In some cases, the term “precursor” can refer to a compound that participates in the chemical reaction that produces another compound, particularly a compound that constitutes a film matrix or a main skeleton of a film. The term “reactant” can be used interchangeably with the term precursor.

In this disclosure, the following abbreviations of chemical structures are used: Cp stands for cyclopentadienyl, Me stands for methyl; Et stands for ethyl; n-Pr stands for n-propyl; i-Pr stands for i-propyl or isopropyl, n-Bu stands for n-butyl; t-Bu stands for t-butyl or tert-butyl.

In the present description, technology is described that relates to remotely doped transistors comprising at least one channel. Inclusion of at least one remote dopant layer comprising at least one boron-containing material into the transistor structure may improve and simultaneously control the electrical performance of such remotely doped transistors.

Accordingly, various embodiments of the present disclosure relate to a field-effect transistor (FET) comprising: a substrate; at least one channel layer comprising a channel material; optionally, at least one insulating layer; a source electrode and a drain electrode in electrical contact with the channel layer; at least one gate electrode in contact with a gate insulating layer; at least one remote dopant layer in electrical contact with at least a portion of the gate electrode or the gate insulating layer; wherein the remote dopant layer comprises at least one boron-containing material; and wherein the remote dopant layer is configured for remote doping of the channel material of the channel layer.

In particular embodiments, the FET comprises: a substrate; at least one channel layer comprising a two-dimensional (2D) channel material; optionally, at least one insulating layer; a source electrode and a drain electrode in electrical contact with the channel layer; at least one gate electrode in contact with a gate insulating layer; at least one remote dopant layer in electrical contact with at least a portion of the gate electrode or the gate insulating layer; wherein the remote dopant layer comprises at least one boron-containing material; and wherein the remote dopant layer is configured for remote doping of the 2D channel material of the channel layer.

In particular embodiments, the FET comprises: a substrate; at least one channel layer comprising a 2D transition metal dichalcogenide (TMDC) material; optionally, at least one insulating layer; a source electrode and a drain electrode in electrical contact with the channel layer; at least one gate electrode in contact with a gate insulating layer; at least one remote dopant layer in electrical contact with at least a portion of the gate electrode or the gate insulating layer; wherein the remote dopant layer comprises at least one boron-containing material; and wherein the remote dopant layer is configured for remote doping of the 2D TMDC material of the channel layer.

A FET as disclosed herein comprises a source and a drain electrode in physical and/or electrical contact with at least one channel layer and at least one gate electrode. The gate electrode is further in contact with a gate insulating layer. The gate insulating layer may comprise at least one insulating material selected from the group consisting of silicon, silicon dioxide, and a high-k dielectric as defined herein.

In some embodiments, the gate insulating layer may be in electrical contact with the channel layer. In some further embodiments, the gate insulating layer may be arranged between the gate electrode and the channel layer and may be in electrical contact with the gate electrode and the channel layer.

Hence, in some embodiments, the gate electrode and the corresponding gate insulating layer may be disposed or positioned adjacent to or in physical contact with the channel layer. This configuration allows an external electric field to be applied to the channel (and/or the at least one remote dopant layer), so as to modulate (and/or turn on or off) current flowing in the channel layer.

Many alternative geometries, schemes and methods known in the art for electrically connecting or physically orienting the source and drain electrode, and/or the gate electrode(s) and/or gate insulating layer(s) with respect to the channel layer(s) can be employed (e.g. top gate or bottom gate) as an alternative or in combination with the embodiments disclosed herein.

Hence, the herein disclosed FET may comprise a stack or structure of various electrodes and layers. A “film” or “layer” as referred to herein may be any continuous or non-continuous structure and material, such as material deposited according to the present technology. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules.

In some embodiments a film or layer may comprise material or a layer with pinholes, which may or may not be continuous.

One of the core layers in the present disclosure is the channel layer comprising a channel material, whose dimensions, chemical, physical, and electrical properties can be particularly suitable for the purpose of conducting electrical current through a transistor device. Non-limiting examples of suitable channel material(s) include semiconducting oxides, elemental semiconductors, alloys, and/or 2D materials such as graphene and 2D TMDC. For instance, a high electrical carrier mobility, and relatively low resistance, of a 2D TMDC material may provide that electrical holes or electrons can be conducted through the channel layer with high efficiency.

The term “2D (channel) material as used herein may generally refer to a layered atomic structure consisting of about a single layer of atoms that is suitable for use as a channel material as described herein.

The term “two-dimensional (2D) transition metal dichalcogenide” (TMDC), as used herein, generally refers to a substantially crystalline material characterized by a layered atomic structure consisting of about a single layer of transition metal atoms sandwiched or arranged between about two layers of chalcogen atoms. In this structure, each transition metal atom is typically covalently bonded to two chalcogen atoms, which may form a hexagonal lattice.

In some embodiments, the 2D TMDC material may comprise a transition metal dichalcogenide represented by the general chemical formula MX₂, wherein M is a transition metal element selected from the group consisting of Mo, W, Bi, Sb, Ti, Pt, Nb, Re, Ta, Ni, Zr, Hf, V, Ta, and Pd; and wherein X is a chalcogenide selected from the group consisting of S, Se, and Te. Advantageously a channel comprising a channel material as described herein can provide improved electronic and mechanical properties. For instance, a channel comprising the disclosed channel material(s) may be characterized by a controlled channel thickness, high charge carrier mobility, low power consumption, and good chemical stability.

In particular embodiments, the channel material may comprise a transition metal dichalcogenide selected from the group consisting of BiS₂, BiSe₂, BiTe₂, MoS₂, MoSe₂, MoTe₂, PtS₂, PtSe₂, PtTe₂, WS₂, WSe₂, WTe₂, PdS₂, PdSe₂, PdTe₂, HfS₂, HfSe₂, HfTe₂, NbS₂, NbSe₂, NbTe₂, ZrS₂, ZrSe₂, ZrTe₂, VS₂, VSe₂, VTe₂, ReS₂, ReSe₂, ReTe₂, NiS₂, NiSe₂, NiTe₂, TaS₂, TaSe₂, TaTe₂, SbS₂, SbSe₂, SbTe₂, TiS₂, TiSe₂, TiTe₂, and mixtures thereof.

In particular embodiments, the channel material may comprise a semiconducting oxide selected from the group consisting of indium tin oxide, indium zinc oxide, gallium zinc oxide, indium oxide, tin oxide, zinc oxide, titanium oxide, gallium oxide, and mixtures thereof.

In particular embodiments, the channel material may comprise an elemental semiconductor selected from the group consisting of Si, Sb, Ge, and combinations thereof.

In particular embodiments, the channel material may comprise graphene.

In particular embodiments, the channel material may comprise a chalcogenide alloy such as Se—Te or Ge—Se—Te.

In particular embodiments, the FET as disclosed herein provides that the at least one channel layer comprising a channel material may have an average thickness between 0.05 nm and 4.0 nm, or between 0.05 nm and 3.80 nm, or between 0.05 nm and 3.60 nm, or between 0.05 nm and 3.50 nm, or between 0.05 nm and 3.40 nm, or between 0.05 nm and 3.20 nm, or between 0.05 nm and 3.0 nm, or between 0.05 nm and 2.80 nm, or between 0.05 nm and 2.60 nm, preferably between 0.05 nm and 2.50 nm, or between 0.05 nm and 2.40 nm, or between 0.05 nm and 2.20 nm, preferably between 0.05 nm and 2.0 nm, or between 0.05 nm and 1.80 nm, or between 0.05 nm and 1.50 nm, or between 0.05 nm and 1.25 nm, or between 0.05 and 1.0 nm.

In some embodiments, the at least one channel layer comprising a channel material may have an average thickness of less than 1.0 nm. The thin channel(s) as disclosed herein provide(s) the advantage that related devices can be further scaled down and are characterized by a sharp transition between an on and off state for a flow of electrical current.

Another core layer of the present disclosure is the at least one remote dopant layer that is in electrical contact with at least a portion of the gate electrode or the gate insulating layer. The remote dopant layer as described herein comprises at least one boron-containing material as a dopant material. As will be described later in the present disclosure, the inclusion of one or more boron-containing material(s) can be used to achieve remote doping of at least a part of the channel material of the channel layer during operation of the field-effect transistor.

In particular embodiments, the FET as disclosed herein provides that the boron-containing material may be selected from the group consisting of boron nitride (BN), boron carbide (BC), boron carbon nitride (BCN), and mixtures thereof.

In some embodiments, the boron nitride (BN) may be amorphous boron nitride (aBN), polycrystalline boron nitride and/or crystalline boron nitride. The boron-containing material as disclosed herein may yield remote dopant layers having a low dielectric constant and good diffusion resistance, resulting in controlled doping of physically remote layers, without sacrificing the stability of the remote dopant film.

In particular embodiments, the FET as disclosed herein provides that the remote dopant layer may be in electrical contact with at least a portion of the channel layer. This has the advantage that diffusion of charge carriers can be more easily modulated.

In particular embodiments, the FET as disclosed herein, may further comprise a spacer layer, disposed between the channel layer and the remote dopant layer. A spacer layer, as used herein, may comprise at least one insulating material, wherein the insulating material is typically not doped. The insulating layer can reversibly mediate or even impede the transfer of holes or electrons between the channel layer and the remote dopant layer. Hence, one function of the spacer layer is to effect and/or improve the ability to “turn off” current flow in the channel layer(s) in response to the application of appropriate voltages to the gate electrode(s), by drawing holes or electrons toward, or driving them away from the channel layer(s).

In particular embodiments, the FET as disclosed herein provides that the spacer layer may be in electrical contact with the channel layer and the remote dopant layer.

Optionally, the remote dopant layer may further comprise at least one hole transport material and/or at least one electron transport material. A function of the remote dopant layer is to supply additional current carriers (holes or electrons) to the channel(s) and/or spacer layer(s), so as to substantially increase or decrease the electrical conductivity (or current flow) in the channel layer(s). Advantageously, a FET having a remote dopant layer configured for remote doping of the channel material of the channel layer may provide controlled and localized doping of the access and contact regions of the FET, which is difficult to achieve in state-of-the-art transistors.

The aforementioned components of the FET as described herein are formed or deposited over a supporting but typically non-conducting substrate. As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material. In particular embodiments, the substrate may comprise silicon, silicon germanium, silicon oxide, gallium arsenide, gallium nitride or silicon carbide.

In some embodiments, the FET as disclosed herein may comprise at least one insulating layer. Said insulating layer may comprise at least one insulating material, wherein said insulating material may be selected from the group consisting of silicon, silicon oxide, and a high-k dielectric material as defined herein.

Referring back to the many alternative schemes and methods for electrically connecting or physically orienting the FET components, the present disclosure provides some non-limiting exemplary embodiments of some geometries and configurations.

In particular embodiments, the FET as disclosed herein may further comprise at least one second remote dopant layer in electrical contact with at least a portion of the gate electrode or the gate insulating layer; wherein the gate electrode or the gate insulating layer is disposed between the first remote dopant layer and the second remote dopant layer; and wherein the second remote dopant layer comprises at least one boron-containing material configured for the remote doping of the channel material of the channel layer. The first remote dopant layer and the second remote dopant may provide remote doping to different regions of the channel layer. In some embodiments, the first remote dopant layer and the second remote dopant layer may be a continuous or non-continuous structure, thus providing the ability to have patterned, controlled and/or local doping of the channel layer. Hence, the present technology offers high versatility in designing various transistor configurations.

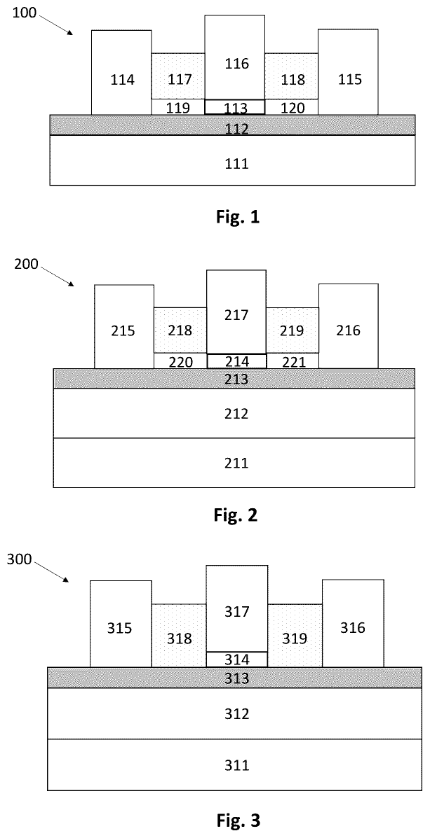

FIG. 1. illustrates an exemplary embodiment of a single gate field-effect transistor (100) of the disclosure. Said single gate transistor (100) may be formed by means of a deposition method and/or system as described herein. In the illustrated example, the single gate transistor (100) comprises a substrate (111), a channel layer (112) positioned on the substrate (111), and a gate insulating layer (113), a first spacer layer (119) and a second spacer layer (120) all positioned on the channel layer (112). The gate insulating layer (113) separates the first spacer layer (119) and a second spacer layer (120). The channel layer (112) comprises a channel material, configured to provide high conductivity, as described herein.

The transistor (100) further comprises a gate electrode (116) positioned on the gate insulating layer (113), a first remote dopant layer (117) positioned on the first spacer layer (119), and a second remote dopant layer (118) positioned on the second spacer layer (120). The gate electrode (116) separates the first remote dopant layer (117) and the second remote dopant layer (118). The first remote dopant layer (117) and the second remote dopant layer (118) each comprise at least one boron-containing material.

The transistor (100) further still comprises a source electrode (114) positioned on one end of the channel layer (112), adjacent to the first remote dopant layer (117), and a drain electrode (115) positioned on the other end of the channel layer (112), and adjacent to the second remote dopant layer (118).

FIG. 2. illustrates another exemplary embodiment of a single gate field-effect transistor (200) of the disclosure. Said single gate transistor (200) may be formed by means of a deposition method and/or system as described herein. In the illustrated example, the single gate transistor (200) comprises a substrate (211), an insulating layer (212) positioned on the substrate (211), a channel layer (213) positioned on the insulating layer (212). The channel layer (213) comprises a channel material as described herein.

The transistor (200) further comprises a gate insulating layer (214) positioned on the channel layer (213). The gate insulating layer (214) separates a first spacer layer (220) and a second spacer layer (221), both also positioned on the channel layer (213). The transistor (200) further comprises a gate electrode (217) positioned on the gate insulating layer (214). The gate electrode (217) separates a first remote dopant layer (218) positioned on the first spacer layer (220), and a second remote dopant layer (219) positioned on the second spacer layer (221). The first remote dopant layer (218) and the second remote dopant layer (219) each comprise at least one boron-containing material.

The transistor (200) further still comprises a source electrode (215) positioned on one end of the channel layer (213) and adjacent to the first remote dopant layer (218), and a drain electrode (216) positioned on the opposite end of the channel layer (213) and adjacent to the second remote dopant layer (219).

FIG. 3. illustrates another exemplary embodiment of a single gate field-effect transistor (300) of the disclosure. Said single gate transistor (300) may be formed by means of a deposition method and/or system as described herein. In the illustrated example, the single gate transistor (300) comprises a substrate (311), an insulating layer (312) positioned on the substrate (311), and a channel layer (313) positioned on the insulating layer (312). The channel layer (313) comprises a channel material as described herein.

The transistor (300) further comprises a gate insulating layer (314) positioned on the channel layer (313) and a gate electrode (317) positioned on the gate insulating layer (314). The gate insulating layer (314) and a gate electrode (317) separate a first remote dopant layer (318) and a second remote dopant layer (319), both positioned on the channel layer (313). The first remote dopant layer (318) and the second remote dopant layer (319) each comprise at least one boron-containing material.

The transistor (300) further still comprises a source electrode (315) positioned on one end of the channel layer (313) and adjacent to the first remote dopant layer (318), and a drain electrode (316) positioned on the other end of the channel layer (313) and adjacent to the second remote dopant layer (319).

It should be noted that the herein described FET is not limited to a single gate structure, but may also comprise multi gate devices (i.e., Fin Field-Effect Transistors). The multi gate device design has the advantage that it can provide better electrostatic control over one or more channel layer, allowing for more precise modulation of the on and off states of the FET. Moreover, more precise switching between the on and off state reduces leakage currents, leading to a FET with higher energy efficiency.

In particular embodiments, the FET as disclosed herein may further comprise at least one second gate electrode in contact with a gate insulating layer; wherein the at least one channel layer is disposed between the first and the second gate electrodes; wherein the field-effect transistor further comprises at least one second remote dopant layer, in electrical contact with at least a portion of the second gate electrode or the gate insulating layer; and wherein the second remote dopant layer comprises at least one boron-containing material configured for the remote doping of the channel material of the channel layer.

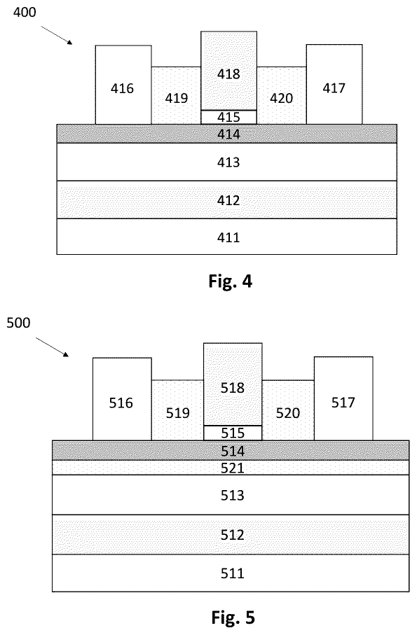

FIG. 4. illustrates an exemplary embodiment of a double gate field-effect transistor (400) of the disclosure. Said double gate transistor (400) may be formed by means of a deposition method and/or system as described herein. In the illustrated example, the double gate transistor (400) comprises a substrate (411), a second gate electrode (412) positioned on the substrate (411), a second gate insulating layer (413) positioned on the second gate electrode (412), and a channel layer (414) positioned on the second gate insulating layer (413). The channel layer (414) comprises a channel material, configured to provide high conductivity, as described herein.

The transistor (400) further comprises a first gate insulating layer (415) positioned on the channel layer (414), a first gate electrode (418) positioned on the first gate insulating layer (415). The first gate insulating layer (415) and the first gate electrode (418) separate a first remote dopant layer (419) and a second remote dopant layer (420), both dopant layers positioned on the channel layer (414). The first remote dopant layer (419) and the second remote dopant layer (420) each comprise at least one boron-containing material.

The transistor (400) further still comprises a source electrode (416) positioned on one end of the channel layer (414) and adjacent to the first remote dopant layer (419), and a drain electrode (417) positioned on the other end of the channel layer (414) and adjacent to the second remote dopant layer (420).

Optionally, the double gate transistor (400) may comprise an insulating layer arranged between the substrate (411) and the second gate electrode (412).

Optionally, the double gate transistor (400) may comprise a first spacer layer arranged between the channel layer (414) and the first remote dopant layer (419) and/or a second spacer layer arranged between the channel layer (414) and the second remote dopant layer (420).

FIG. 5. illustrates another exemplary embodiment of a double gate field-effect transistor (500) of the disclosure. Said double gate transistor (500) may be formed by means of a deposition method and/or system as described herein. In the illustrated example, the double gate transistor (500) comprises a substrate (511), a second gate electrode (512) positioned on the substrate (511), a second gate insulating layer (513) positioned on the second gate electrode (512).

The transistor (500) further comprises a third remote dopant layer (521) positioned on the second gate insulating layer (513), and a channel layer (514) positioned on the third remote dopant layer (521). The channel layer (514) comprises a channel material as described herein.

The transistor (500) further still comprises a first gate insulating layer (515) positioned on the channel layer (514), and a first gate electrode (518) positioned on the first gate insulating layer (515). The first gate insulating layer (515) and the first gate electrode (518) separate a first remote dopant layer (519), and a second remote dopant layer (520), both positioned on the channel layer (514).

The transistor (500) further still comprises a source electrode (516) positioned on one end of the channel layer (514) and adjacent to the first remote dopant layer (519), and a drain electrode (517) positioned on the other end of the channel layer (514) and adjacent to the second remote dopant layer (520). The first remote dopant layer (519), the second remote dopant layer (520), and the third remote dopant layer (521) each comprise at least one boron-containing material.

Optionally, the double gate transistor (500) may comprise an insulating layer arranged between the substrate (511) and the second gate electrode (512).

Optionally, the double gate transistor (500) may comprise a first spacer layer arranged between the channel layer (514) and the first remote dopant layer (519), a second spacer layer arranged between the channel layer (514) and the second remote dopant layer (520), and/or a third spacer layer arranged between the third remote dopant layer (521) and the channel layer (514).

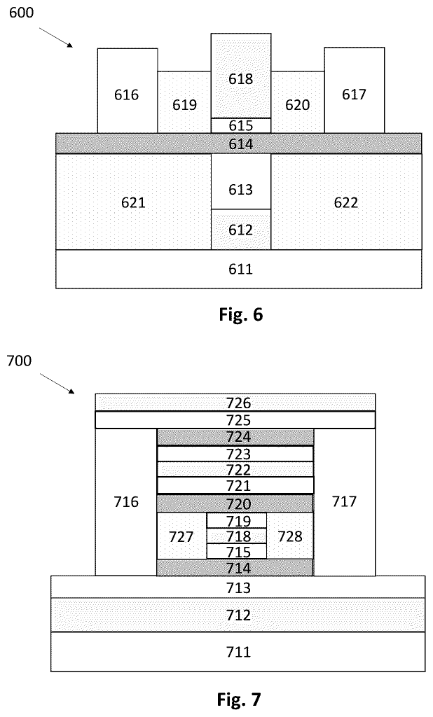

FIG. 6. illustrates another exemplary embodiment of a double gate field-effect transistor (600) of the disclosure. Said double gate transistor (600) may be formed by means of a deposition method and/or system as described herein. In the illustrated example, the double gate transistor (600) comprises a substrate (611), a second gate electrode (612) positioned on the substrate (611), and a second gate insulating layer (613) positioned on the second gate electrode (612). The second gate insulating layer (613) and second gate electrode (612) separate a third remote dopant layer (621) and a fourth remote dopant layer (622), both positioned on the substrate (611).

The transistor (600) further comprises a channel layer (614) positioned on the second gate insulating layer (613), a first gate insulating layer (615) positioned on the channel layer (614), and a first gate electrode (618) positioned on the first gate insulating layer (615). The channel layer (614) comprises a channel material as described herein. The first gate insulating layer (615) and first gate electrode (618) separate a first remote dopant layer (619) and a second remote dopant layer (620), both positioned on the channel layer (614).

The transistor (600) further comprises still a source electrode (616) positioned on one end of the channel layer (614) and adjacent to the first remote dopant layer (619), and a drain electrode (617) positioned on the other end of the channel layer (614) and adjacent to the second remote dopant layer (620).

The first remote dopant layer (619), the second remote dopant layer (620), the third remote dopant layer (621), and the fourth remote dopant layer (622) each comprise at least one boron-containing material as described herein.

Optionally, the double gate transistor (600) may comprise an insulating layer arranged between the substrate (611) and the second gate electrode (612), an additional insulating layer arranged between the substrate (611) and the third remote dopant layer (621), and/or an additional insulating layer arranged between the substrate (611) and the fourth remote dopant layer (622).

Optionally, the double gate transistor (600) may comprise a first spacer layer arranged between the channel layer (614) and the first remote dopant layer (619), a second spacer layer arranged between the channel layer (614) and the second remote dopant layer (620), a third spacer layer arranged between the channel layer (614) and the third remote dopant layer (621) and the channel layer (614), and/or a fourth spacer layer arranged between the channel layer (614) and the fourth remote dopant layer (622).

It should be noted that the herein described FET is not limited to a 2D structure, but may also comprise a three-dimensional (3D) stacked structure. Such a 3D stacked structure may comprise a plurality of gate electrodes surrounding one or more channel region comprising a channel material.

In particular embodiments, the FET as disclosed herein further comprises a plurality of channel layers that are stacked on top of each other and separated in space; wherein each channel layer comprises a channel material; wherein the FET further comprises a plurality of gate electrodes in contact with a gate insulating layer, wherein at least one gate electrode and gate insulating layer is disposed between every two channel layers; wherein the transistor further comprises a plurality of remote dopant layers; wherein at least a portion of every gate electrode or gate insulating layer is in electrical contact with at least one remote dopant layer; and wherein each remote dopant layer comprises at least one boron compound configured for the remote doping of the channel material of at least one channel layer.

FIG. 7. illustrates another exemplary embodiment of a 3D field-effect transistor (700) of the disclosure. Said 3D transistor (700) may be formed by means of a deposition method and/or system as described herein. In the illustrated example, the 3D transistor (700) comprises a substrate (711), a second gate electrode (712) positioned on the substrate (711), a second gate insulating layer (713) positioned on the second gate electrode (712), and a first channel layer (714) positioned on the second gate insulating layer (713). The first channel layer (714) separates a source electrode (716) and a drain electrode (717), both positioned on the second gate insulating layer (713).

The transistor (700) further comprises a first gate insulating layer (715) positioned on the first channel layer (714), a first gate electrode (718) positioned on the first gate insulating layer (715), and a third gate insulating layer (719) positioned on the first gate electrode (718).

The first gate insulating layer (715), first gate electrode (718), and third gate insulating layer (719) separate a first remote dopant layer (727) and a second remote dopant layer (728), both positioned on the first channel layer (714).

The transistor (700) further still comprises a second channel layer (720) positioned on the third gate insulating layer (719), a fourth gate insulating layer (721) positioned on the second channel layer (720), a third gate electrode (722) positioned on the fourth gate insulating layer (721), a fifth gate insulating layer (723) positioned on the third gate electrode (722), and a third channel layer (724) positioned on the fifth gate insulating layer (723).

The transistor (700) further still comprises a sixth gate insulating layer (725) positioned on the third channel layer (724), and a fourth gate electrode (726) positioned on the sixth gate insulating layer (725); wherein each channel layer comprises a channel material; and wherein each remote dopant layer comprises at least one boron-containing material.

Optionally, the 3D transistor (700) may comprise an insulating layer arranged between the substrate (711) and the second gate electrode (712), and/or an additional insulating layer positioned on the fourth gate electrode (726).

Optionally, the 3D transistor (700) may comprise a first spacer layer arranged between the first channel layer (714) and the first remote dopant layer (727), and/or a second spacer layer arranged between the first channel layer (714) and the second remote dopant layer (728).

Optionally, the 3D transistor (700) may comprise a third remote dopant layer arranged between the second gate insulating layer (713) and the first channel layer (714).

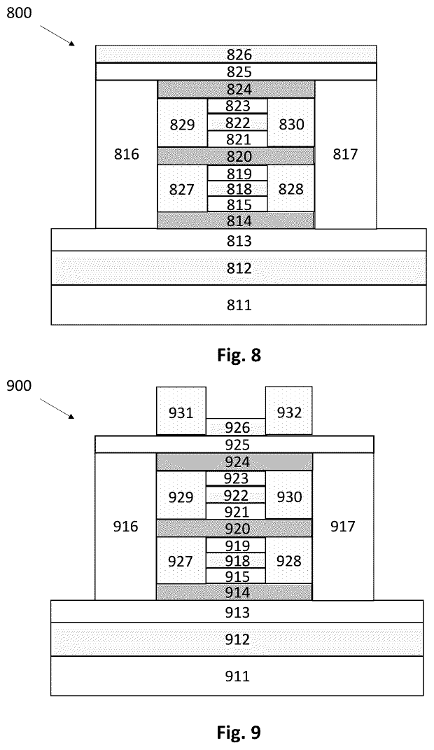

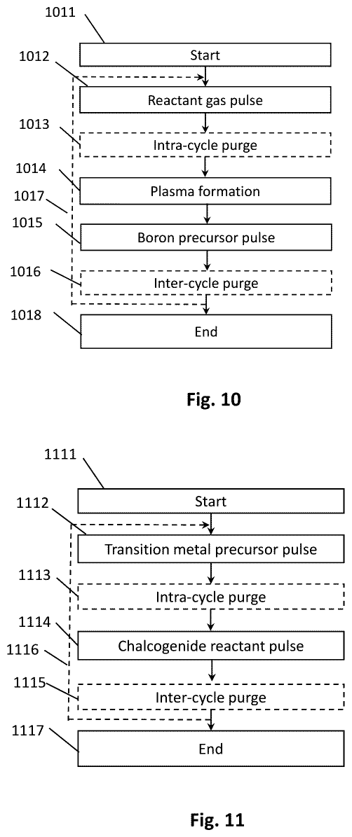

FIG. 8. illustrates another exemplary embodiment of a 3D field-effect transistor (800) of the disclosure. Said 3D transistor (800) may be formed by means of a deposition method and/or system as described herein. In the illustrated example, the 3D transistor (800) comprises a substrate (811), a second gate electrode (812) positioned on the substrate (811), a second gate insulating layer (813) positioned on the second gate electrode (812), and a first channel layer (814) positioned on the second gate insulating layer (813). The first channel layer (814) separates a source electrode (816), and a drain electrode (817) positioned on the second gate insulating layer (813).

The transistor (800) further comprises a first gate insulating layer (815) positioned on the first channel layer (814), a first gate electrode (818) positioned on the first gate insulating layer (815), and a third gate insulating layer (819) positioned on the first gate electrode (818). The first gate insulating layer (815), first gate electrode (818), and third gate insulating layer (819) separate a first remote dopant layer (827) and a second remote dopant layer (828), both positioned on the first channel layer (814).

The transistor (800) further still comprises a second channel layer (820) positioned on the third gate insulating layer (819), a fourth gate insulating layer (821) positioned on the second channel layer (820), a third gate electrode (822) positioned on the fourth gate insulating layer (821), and a fifth gate insulating layer (823) positioned on the third gate electrode (822). The fourth gate insulating layer (821), third gate electrode (822), and fifth gate insulating layer (821) separate a third remote dopant layer (829) and a fourth remote dopant layer (830), both positioned on the second channel layer (820).

The transistor (800) further still comprises a third channel layer (824) positioned on the fifth gate insulating layer (823), a sixth gate insulating layer (825) positioned on the third channel layer (824), and a fourth gate electrode (826) positioned on the sixth gate insulating layer (825); wherein each channel layer comprises a channel material; and wherein each remote dopant layer comprises at least one boron-containing material.

Optionally, the 3D transistor (800) may comprise an additional insulating layer arranged between the substrate (811) and the second gate electrode (812), and/or an additional insulating layer positioned on the fourth gate electrode (826).

Optionally, the 3D transistor (800) may comprise a first spacer layer arranged between the first channel layer (814) and the first remote dopant layer (827), a second spacer layer arranged between the first channel layer (814) and the second remote dopant layer (828), a third spacer layer arranged between the second channel layer (820) and the third remote dopant layer (829), and/or a fourth spacer layer arranged between the second channel layer (820) and the fourth remote dopant layer (830).

Optionally, the 3D transistor (800) may comprise a fifth remote dopant layer arranged between the second gate insulating layer (813) and the first channel layer (814).

FIG. 9. illustrates another exemplary embodiment of a 3D field-effect transistor (900) of the disclosure. Said 3D transistor (900) may be formed by means of a deposition method and/or system as described herein. In the illustrated example, the 3D transistor (900) comprises a substrate (911), a second gate electrode (912) positioned on the substrate (911), a second gate insulating layer (913) positioned on the second gate electrode (912), and a first channel layer (914) positioned on the second gate insulating layer (913). The first channel layer (914) separates a source electrode (916), and a drain electrode (917) positioned on the second gate insulating layer (913).

The transistor (900) further comprises a first gate insulating layer (915) positioned on the first channel layer (914), a first gate electrode (918) positioned on the first gate insulating layer (915), and a third gate insulating layer (919) positioned on the first gate electrode (918). The first gate insulating layer (915), first gate electrode (918), and third gate insulating layer (919) separate a first remote dopant layer (927) and a second remote dopant layer (928), both positioned on the first channel layer (914).

The transistor (900) further still comprises a second channel layer (920) positioned on the third gate insulating layer (919), a fourth gate insulating layer (921) positioned on the second channel layer (920), a third gate electrode (922) positioned on the fourth gate insulating layer (921), and a fifth gate insulating layer (923) positioned on the third gate electrode (922). The fourth gate insulating layer (921), third gate electrode (922), and fifth gate insulating layer (923) separate a third remote dopant layer (929) and a fourth remote dopant layer (930), both positioned on the second channel layer (920).

The transistor (900) further still comprises a third channel layer (924) positioned on the fifth gate insulating layer (923), a sixth gate insulating layer (925) positioned on the third channel layer (924), and a fourth gate electrode (926) positioned on the sixth gate insulating layer (925) and separating a fifth remote dopant layer (931) and a sixth remote dopant layer (932) positioned on the sixth gate insulating layer (925); wherein each channel layer comprises a channel material; and wherein each remote dopant layer comprises at least one boron-containing material.

Optionally, the 3D transistor (900) may comprise an additional insulating layer arranged between the substrate (911) and the second gate electrode (912), and/or an additional insulating layer positioned on the fourth gate electrode (926).

Optionally, the 3D transistor (900) may comprise a first spacer layer arranged between the first channel layer (914) and the first remote dopant layer (927), a second spacer layer arranged between the first channel layer (914) and the second remote dopant layer (928), a third spacer layer arranged between the second channel layer (920) and the third remote dopant layer (929), a fourth spacer layer arranged between the second channel layer (920) and the fourth remote dopant layer (930), a fifth spacer layer arranged between the sixth gate insulating layer (925) and the fifth remote dopant layer (931), and/or a sixth spacer layer arranged between the sixth gate insulating layer (925) and the sixth remote dopant layer (932).

Optionally, the 3D transistor (900) may comprise a seventh remote dopant layer arranged between the second gate insulating layer (913) and the first channel layer (914).

Another aspect of the disclosure relates to a method for the manufacturing of at least a portion of a field-effect transistor (FET), comprising the steps of: a) providing a substrate into a reaction chamber; b) executing one or more cycles, a cycle comprising a boron precursor pulse, wherein at least a part of the substrate is contacted with at least one boron precursor by introducing the boron precursor into the reaction chamber; wherein, as a result of the cycles, at least one remote dopant layer comprising at least one boron-containing material is formed on the substrate; wherein the substrate comprises at least one channel layer comprising a channel material that is formed before and/or after the forming of the remote dopant layer, or a combination thereof; wherein the at least one remote dopant layer is configured for the remote doping of the channel material of the channel layer during operation of the field-effect transistor.

In particular embodiments, the (remote dopant layer forming) cycle may further comprise a reactant gas pulse, wherein at least a part of the substrate is contacted with at least one reactant gas, preferably comprising nitrogen, by introducing the reactant gas into the reaction chamber.

In particular embodiments, the method as disclosed herein provides that the substrate may further comprise a spacer layer; and wherein the spacer layer is arranged between the channel layer and the remote dopant layer.

In particular embodiments, the method as disclosed herein provides that the substrate may further comprise an insulating layer; and wherein the insulating layer is arranged between the channel layer and the substrate.

In some embodiments, wherein the at least one remote dopant layer is formed before the at least one channel layer comprising a channel material, said remote dopant layer(s) may be disposed between the substrate and the channel layer(s) comprising a channel material.

In some embodiments, wherein the at least one remote dopant layer is formed after the at least one channel layer comprising a channel material, said remote dopant layer(s) may be positioned on the channel layer(s) comprising a channel material. Optionally, a spacer layer may be arranged between said remote dopant layer(s) and said channel layer(s) comprising a channel material.

In some embodiments, wherein the at least one remote dopant layer is formed before and after the formation of the at least one channel layer comprising a channel material, said remote dopant layer(s) may be disposed between the substrate and the channel layer(s) comprising a channel material and may be positioned on the channel layer(s) comprising a channel material. Optionally, a spacer layer may be arranged between said remote dopant layer(s) and said channel layer(s) comprising a channel material.

In particular embodiments, the method as disclosed herein provides that the boron-containing material may be selected from the group consisting of boron nitride (BN), boron carbide (BC), boron carbon nitride (BCN), and mixtures thereof. In some embodiments, the boron nitride (BN) may be amorphous boron nitride (aBN), polycrystalline boron nitride and/or crystalline boron nitride. An exemplary method for depositing a boron nitride film is described in U.S. patent application Ser. No. 17/966,660, which is incorporated herein by reference, except for any disclaimers and inconsistencies.

In particular embodiments, the method as disclosed herein provides that the at least one channel layer may be formed by: A) providing the substrate to the reaction chamber; B) executing one or more cycles, a cycle comprising i. a transition metal precursor pulse, wherein at least a part of the substrate is contacted with at least one transition metal precursor by introducing the transition metal precursor into the reaction chamber; ii. a chalcogenide reactant pulse, wherein at least a part of the substrate is contacted with at least one chalcogenide reactant by introducing the chalcogenide reactant into the reaction chamber; wherein, as a result of the cycles, at least one channel layer comprising a channel material, preferably a 2D TMDC material, is formed on the substrate and/or the remote dopant layer.

In particular, the formation of the at least one remote dopant layer comprising at least one boron-containing material and/or the at least one channel layer comprising a channel material as described herein may relate to a cyclical deposition process, such as an atomic layer deposition (ALD) process or a cyclical chemical vapor deposition (CVD) process. The cyclical deposition process comprises one or more cycles.

In particular embodiments, the method as disclosed herein may be an ALD method. In contrast to sputtering techniques commonly used within the state of the art for deposition of thin films and layers for the manufacturing of various semiconductors and transistors, cyclical deposition processes such as ALD were found to provide more uniform deposition across the surface of the substrate.

As used herein, the synonymous terms “deposition” or “cyclic deposition” or “cyclic deposition process” or “cyclical deposition process” refer to a sequential introduction of precursors (and/or reactants) into a reaction chamber to deposit a layer or film over a substrate and includes processing techniques such as ALD, CVD, and hybrid cyclical deposition processes that include an ALD component and a CVD component. Typically, one deposition cycle may form a film or layer of about 0.10 nm. However, the experimental thickness may vary depending on the amount and type of cycles and available reaction sites on the substrate and/or a previously deposited layer.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor (e.g. a boron precursor or transition metal precursor) is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas such as a chalcogenide reactant or nitrogen reactant) may subsequently be introduced into the process chamber. The reactant can be capable of further reaction with the precursor. Purging steps can be utilized during one or more repetitions, e.g., during each deposition step, to remove any excess precursor from the process chamber and/or remove any excess reactant and/or reaction byproducts from the reaction chamber. Note that, in several embodiments as described herein, ALD processes are not necessarily comprised of a sequence of self-limiting surface reactions.

As used herein, the term “purge” may refer to a procedure in which an inert or substantially inert gas is provided to a reaction chamber in between two pulses of gasses that react with each other. For example, a purge, e.g., using an inert gas such as a noble gas, may be provided between subsequent pulses, thus avoiding, or at least minimizing gas phase interactions between precursor(s) and/or reactant(s).

In particular embodiments, the method as disclosed herein provides that the reaction chamber is purged before and/or after each boron precursor pulse. In particular embodiments, the method as disclosed herein provides that the reaction chamber is purged before and/or after each transition metal precursor pulse and chalcogenide reactant pulse.

Advantageously, a cyclical deposition process as disclosed herein can be a thermal deposition process. In other words, in some embodiments, none of the pulses or purges in the cyclical deposition process employs a plasma. In the case of thermal cyclical deposition processes, a duration of the step of providing the boron precursor to the reaction chamber, a duration of the step of providing the transition metal precursor to the reaction chamber, and/or a duration of the step of providing the chalcogenide reactant to the reaction chamber can be relatively long to allow the precursors and/or reactants to react with a surface of the substrate and/or a previously deposited layer. For example, the duration can be greater than or equal to 5 seconds or greater than or equal to 10 seconds or between about 5 and 10 seconds.

In some embodiments, the cyclical deposition process may employ a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical depositing process may comprise generating a plasma in the reaction chamber.

In some embodiments, the method as disclosed herein may be a continuous vacuum deposition process. In the context of a continuous vacuum deposition process, a material is deposited onto a substrate in a reaction chamber without the introduction of atmospheric air or any interruptions that would break the controlled vacuum environment. This process involves maintaining a consistent vacuum pressure within the reaction chamber.

In particular embodiments, the method as disclosed herein provides that the remote dopant layer may be formed without any intervening vacuum break. In particular embodiments, the method as disclosed herein provides that the at least one channel layer and the at least one remote dopant layer may be formed in the same reaction chamber without any intervening vacuum break. This has the advantage that the present disclosure avoids the need for repeated evacuations and purges of the reaction chamber that are common in traditional batch deposition methods.

In particular embodiments, the method as disclosed herein for the formation of the at least one remote dopant layer comprising at least one boron-containing material and/or the at least one channel layer comprising a channel material may comprise at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles.

In some embodiments, the steps may be repeated from at least 1 cycle to at most 1000 cycles, or from at least 2 cycles to at most 100 cycles, or from at least 5 cycles to at most 50 cycles.

In particular embodiments, the method as disclosed herein provides that the remote dopant layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In particular embodiments, the method as disclosed herein provides that the channel layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In some embodiments, the at least one remote dopant layer comprising at least one boron-containing material and/or the at least one channel layer comprising a channel material may have a growth rate of 0.10 nm or less per cycle of precursor(s)/reactive gas(es), and purge (e.g., inert carrier) gas(es). A layer of lower thickness may be desirable for many electronics applications, including transistors.

The method as disclosed herein relies on the execution of one or more cycles to grow at least one thin-film remote dopant layer, and in some embodiments, at least one channel layer. An exemplary cycle for forming a remote dopant layer is described in U.S. patent application Ser. No. 17/966,660, which is incorporated herein by reference, except for any disclaimers and inconsistencies.

A cycle may comprise one or more pulses. In some embodiments, at least one pulse involves a self-limiting surface reaction. In some embodiments, all pulses involve a self-limiting surface reaction. In the present context, a self-limiting surface reaction refers to a chemical reaction that automatically halts or slows down once a certain threshold or coverage is reached on a surface, for instance, once a complete monolayer or sub-monolayer is formed the reactions stops by preventing further reaction with additional precursor. In some embodiments, a cycle comprises one or more precursor pulse and/or one or more reactant pulse.

In some embodiments, a cycle to grow a channel layer may comprise the following sequence of pulses: a transition metal precursor pulse and a chalcogenide reactant pulse. In the transition metal precursor pulse one or more transition metal precursor is provided into the reaction chamber and may chemisorb to the substrate (i.e., adheres and forms chemical bonds with atoms or molecules on the surface of said substrate). In the chalcogenide reactant pulse, one or more chalcogenide reactant is provided into the reaction chamber and may react with the chemisorbed transition metal to form a channel material or layer on at least a part of the substrate. The number of cycles of the method as disclosed herein determines the overall thickness of the deposited channel layer. An advantage of the presently disclosed cyclical deposition process is the precise control over said overall layer thickness and dopant incorporation.

10. describes an exemplary embodiment of the method as described herein for the manufacturing of at least a portion of a field-effect transistor as disclosed herein. The method starts (1011) after a substrate has been provided to a reaction chamber. The cyclical deposition process comprises providing a reactant gas into the reaction chamber in a reactant gas pulse (1012). Optionally, the reaction chamber is purged (1013) after the reactant gas pulse (1012).

Then, a plasma is formed using the reactant gas (1014) and one or more boron precursor(s) is contacted with at least a part of the substrate in a boron precursor pulse (1015). Optionally, the reaction chamber can be purged (1016) after the boron precursor pulse. The sequence of the reactant gas pulse (1012), formation of the plasma (1014), the boron precursor pulse (1015), and the optional purges (1013, 1016) can be repeated (1017) any number of times to obtain a desired thickness of the remote dopant layer as disclosed.

The method concludes (1018) when a remote dopant layer having the desired thickness is formed based on any combination of the aforementioned steps. Once the method has ended, the substrate can be subjected to additional processes known in the art for forming a device structure and/or device.

It should be noted that the reactant gas pulse (1012), formation of the plasma (1014), and the boron precursor pulse (1015) may overlap in a cycle. Further, the sequence of each method step (1012 to 1016) within each cycle may vary. For instance, and in another exemplary embodiment, a cycle may comprise the consecutive steps of a boron precursor pulse, a reactant gas pulse, and the formation of a plasma.

11. describes an exemplary embodiment of the method as described herein for the manufacturing of at least a portion of a field-effect transistor as disclosed herein. The method starts (1111) after a substrate has been provided to a reaction chamber. The cyclical deposition process comprises contacting one or more transition metal precursor(s) with at least a part of the substrate in a transition metal precursor pulse (1112). Optionally, the reaction chamber is purged (1113) after the transition metal precursor pulse (1112). Then, one or more chalcogenide reactant(s) is provided to the reaction chamber in a chalcogenide reactant pulse (1114). Optionally, the reaction chamber can be purged (1115) after the chalcogenide reactant pulse.

The transition metal precursor pulse (1112), the chalcogenide reactant pulse (1114), and the optional purges (1113,1115) can be repeated (1116) any number of times to obtain a desired thickness of a channel layer.

The method concludes (1117) when a remote dopant layer having the desired thickness is formed based on any combination of the aforementioned steps. Once the method has ended, the substrate can be subjected to additional processes known in the art for forming a device structure and/or device.

It should be noted that the transition metal precursor pulse (1112) and the chalcogenide reactant pulse (1114) may overlap in a cycle. Further, the sequence of each method step (1112 to 1115) within each cycle may vary. For instance, and in another exemplary embodiment, a cycle may comprise the consecutive steps of a chalcogenide reactant pulse and a transition metal precursor pulse. Hence, a chalcogenide reactant pulse may precede a transition metal precursor pulse.

In particular embodiments, the method as disclosed herein provides that the boron precursor pulse, the transition metal precursor pulse, the chalcogenide reactant pulse, and/or the reactant gas pulse comprise a plurality of micro pulses. A “micro pulse” as used herein is a short period during which one or more boron precursor(s), one or more transition metal precursor(s), one or more chalcogenide reactant(s) and/or one or more reactant gas may be introduced into the reaction chamber. Hence, the method as disclosed herein provides high flexibility in pulse sequence and length, thereby providing a cost-effective and more efficient method than what is disclosed in the state of the art.

In some embodiments, the boron precursor pulse and/or the transition metal precursor pulse may last from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, the chalcogenide reactant pulse and/or the reactant gas pulse may last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

It shall be understood that any two steps and/or pulses and/or micro pulses can be separated by a purge. Thus, in some embodiments, a boron precursor pulse and/or a transition metal precursor pulse, and a chalcogenide reactant pulse and/or a reactant gas pulse may be separated by a purge. In some embodiments, subsequent cycles are separated by a purge.

In particular embodiments, the reaction chamber may be purged before and/or after boron precursor pulse, transition metal precursor pulse, chalcogenide reactant pulse and/or reactant gas pulse. An advantage of purging the reaction chamber before and/or after each precursor pulse and/or reactant pulse is that any residual precursor, reactant, and/or reaction byproduct is removed, thereby avoiding cross-contamination between pulses, and resulting in films or layers with high purity and less defects.

In some particular embodiments, the one or more channel layer(s) and the one or more remote dopant layer(s) may be formed in the same reaction chamber. In some embodiments, the one or more channel layer(s) and the one or more remote dopant layer(s) may be formed consecutively in the same reaction chamber, preferably without any intervening vacuum break.

In some particular embodiments, the one or more channel layer(s) and the one or more remote dopant layer(s) may be formed in a separate reaction chamber.

In the present disclosure, the at least one boron-containing material comprised in the remote dopant layer is purposefully included to create “charge storage sites” or “charge traps” within the remote dopant layer. These charge storage sites can control the trapping and release of charge carriers such as electrons or holes.

It is demonstrated that one or more boron-containing material(s) can be used to achieve remote doping of at least a part of the channel material of the channel layer during operation of the field-effect transistor. In particular, without committing to a specific theory, the cyclical deposition process as disclosed herein may provide an advantage by allowing modulation of the stoichiometry of the boron compound under specific deposition conditions. This modulation is believed to provide either positive or negative (trapped) charges in the remote dopant layer.

Hence, in some particular embodiments, the boron compound may be a p-dopant and/or an n-dopant.

In some particular embodiments, the remote dopant layer may comprise one or more trapped charges.

Various boron precursors may be suitable for the formation of the remote dopant layer comprising at least one boron-containing material.

In some particular embodiments, the method as disclosed herein may provide that the boron precursor is represented by the following general formula (I)

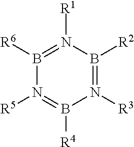

wherein R¹, R², R³, R⁴, R⁵, R⁶ are each independently selected from the group consisting of hydrogen, halogen, alkyl, alkenyl, and alkoxy.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula —CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl, and its isomers (e.g., n-butyl, i-butyl, and t-butyl); pentyl and its isomers, hexyl, and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e., “alkylene,” this is intended to mean the alkyl group as defined herein having two single bonds as points of attachment to other groups. As used herein, the term “alkylene” also referred as “alkanediyl,” by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3-methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C₃₋₂₀alkenyl groups are ethenyl, 2-propenyl, 2-butenyl, 3-butenyl, 2-pentenyl and its isomers, 2-hexenyl and its isomers, 2,4-pentadienyl, and the like.

The term “alkoxy” or “alkyloxy,” as a group or part of a group, refers to a group having the formula —OR^{b} wherein Rb is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

Where an alkylene group is present, connectivity to the molecular structure of which it forms part may be through a common carbon atom or different carbon atom. To illustrate this applying the asterisk nomenclature of this disclosure, a C₃alkylene group may be for example *—CH₂CH₂CH₂—*, *—CH(—CH₂CH₃)—* or *—CH₂CH(—CH₃)—*.

In some embodiments, the method as disclosed herein provides that for the one or boron precursor represented by the general formula (I), the alkyl is a C₁₋₈alkyl, and more in particular a C₁₋₄alkyl. More in particular the alkyl is a C₁, C₂, C₃, C₄, C₅, C₆, C₇, and/or C₈ alkyl.

In some embodiments, the method as disclosed herein provides that for the one or boron precursor represented by the general formula (I), the alkenyl is a C₂₋₈alkenyl, and more in particular a C₂₋₄alkenyl. More in particular the alkenyl is a C₂, C₃, C₄, C₅, C₆, C₇, and/or C₈ alkenyl.

In some embodiments, the method as disclosed herein provides that for the one or boron precursor represented by the general formula (I), the alkoxy is a C₁₋₈alkoxy, and more in particular a C₁₋₄alkoxy. More in particular the alkoxy is a C₁, C₂, C₃, C₄, C₅, C₆, C₇, and/or C₈ alkoxy.

In some embodiments, the present disclosure provides that R¹, R², R³, R⁴, R⁵, R⁶ are each independently selected from the group consisting of hydrogen, halogen, C₁₋₈alkyl, C₂₋₈alkenyl, and C₁₋₈alkoxy.

In some embodiments, the present disclosure provides that R¹, R², R³, R⁴, R⁵, R⁶ are each independently selected from the group consisting of hydrogen, halogen, C₁₋₄alkyl, C₂₋₄alkenyl, and C₁₋₄alkoxy.

In particular embodiments, the method as disclosed herein provides that the one or more boron precursor may comprise borazine or a substituted borazine.

In some particular embodiments, the method as disclosed herein may provide that the boron precursor is selected from the group consisting of BF₃, BCl₃, BBr₃, Bl₃, BH₃, B₂H₆, B₄H₁₀, B₅H₉, B₁₀H₁₄, and mixtures thereof. In the event that the boron precursor does not comprise nitrogen, a reactant gas comprising nitrogen may be supplied to the reaction chamber. In some embodiments, the reactant gas may comprise NH₃.

In various embodiments, a reactant gas comprising one or more of an argon-containing gas and a helium-containing gas may be used during deposition of the one or more boron precursor on the surface of the substrate. In various embodiments, the reactant gas may further comprise hydrogen and/or nitrogen. In various embodiments, the reactant gas may comprise at least one of 30-99% argon and/or helium and 1-70% hydrogen. In various embodiments, the reactant gas may comprise at least one of 10-90% argon and 10-90% nitrogen.

In the present disclosure, one or more transition metal precursor(s) may adhere and bind to a substrate to initiate the formation of one or more channel layer(s) comprising a channel material.

In a particular embodiment, the channel material may comprise a transition metal dichalcogenide selected from the group consisting of MoS₂, MoSe₂, MoTe₂, WS₂, WSe₂, WTe₂, NbS₂, NbSe₂, NbTe₂, VS₂, VSe₂, VTe₂, ReS₂, ReSe₂, ReTe₂, TaS₂, TaSe₂, TaTe₂, and mixtures thereof.

In a particular embodiment, the method as disclosed herein provides that the transition metal precursor may comprise a transition metal in oxidation state +4. Preferably, a transition metal element chosen from the group including at least one of Mo, W, Nb, V, Re, and Ta.

In a particular embodiment, the method as disclosed herein provides that the chalcogenide reactant is selected from the group consisting of H₂S, H₂S plasma, H₂Se, Et₂Se, Se₂(Si(i-Pr)₂)₂, [(CH₃)₃Si]₂Se, [(CH₃)₃Si]₂Te, Te[Oi-Pr]₄, and mixtures thereof.

The method as disclosed herein may be performed at different temperatures and/or pressures. In particular embodiments, the method as disclosed herein provides that the substrate may be heated to a temperature of about 80° C. to about 400° C., or about 100° C. to about 400° C., or about 125° C. to about 400° C., preferably about 150° C. to about 400° C., or about 175° C. to about 400° C., preferably about 200° C. to about 400° C., or about 250° C. to about 400° C., or about 300° C. to about 400° C. The listed temperatures can decrease the time needed for material deposition, although lower or higher temperatures can be considered still.

In particular embodiments, the method as disclosed herein provides that the pressure in the reaction chamber is between about 0.1 Torr and about 100.0 Torr, or between about 0.5 Torr and about 100.0 Torr, or between about 1.0 Torr and about 100.0 Torr, or between about 2.0 Torr and about 100.0 Torr, or between about 5.0 Torr and about 100.0 Torr, or between about 5.0 Torr and about 80.0 Torr, or preferably between about 5.0 Torr and about 50.0 Torr, or between about 10.0 Torr and about 50.0 Torr. The listed pressures can decrease the time needed for material deposition, although lower or higher pressures can be considered still.

The remote dopant layer and/or the channel layer may be formed in any suitable reactor. Thus, in some embodiments, the remote dopant layer and/or the channel layer is deposited in a cross-flow reactor. In some embodiments, the remote dopant layer and/or the channel layer is deposited in a showerhead reactor. In some embodiments, the remote dopant layer and/or the channel layer is deposited in a hot-wall reactor. In some embodiments, the remote dopant layer and/or the channel layer is deposited in a cold-wall reactor. Doing so can advantageously enhance uniformity and/or repeatability of the remote dopant layer and/or the channel layer deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the boron precursor, the transition metal precursor, and/or the chalcogenide reactant is provided to the reaction chamber by means of a carrier gas. Exemplary carrier gas includes nitrogen (N₂) and noble gases such as He, Ne, Ar, Xe, or Kr.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

Another aspect of the present disclosure relates to a system for the manufacturing of at least a portion of a field-effect transistor comprising: a reaction chamber constructed and arranged to hold a substrate; a boron precursor vessel constructed and arranged to contain and evaporate at least one boron precursor; optionally, a reactant gas vessel and a plasma power source; a transition metal precursor vessel constructed and arranged to contain and evaporate at least one transition metal precursor; a chalcogenide reactant vessel constructed and arranged to contain and evaporate at least one chalcogenide reactant; a controller, operatively connected to the boron precursor vessel, the transition metal precursor vessel, and the chalcogenide reactant vessel; wherein the controller is configured to control the introduction of the boron precursor, the transition metal precursor, and the chalcogenide reactant into the reaction chamber during one or more cycles; wherein, as a result of the cycles, at least one remote dopant layer comprising a boron-containing material and at least one channel layer comprising a channel material are formed on the substrate; and wherein the remote dopant layer is configured for remote doping of the channel material comprised in the channel layer during operation of the field-effect transistor.

A controller configured to precisely control the introduction of precursor gas and reactive gas may be particularly advantageous to perform well-controlled chemical reactions that can result in more uniform and reproducible thin films or layers. Moreover, the controller can adjust the flow rate and timing to optimize the reaction kinetics, resulting in desired film properties such as a specific composition of the boron-containing material in the remote dopant layer.

In some embodiments, the boron precursor, the transition metal precursor, the optional reactant gas, and/or the chalcogenide reactant is provided to the reaction chamber from a temperature-controlled vessel. In some embodiments, the temperature-controlled vessel is configured for cooling the precursors and/or reactants. In some embodiments, the temperature-controlled vessel is configured for heating the precursors and/or reactants. In some embodiments, the temperature-controlled vessel is maintained at a temperature of at least −50° C. to at most 20° C., or at a temperature of at least 20° C. to at most 250° C., or at a temperature of at least 100° C. to at most 200° C.

In particular embodiments, the system as disclosed herein is configured to manufacture a field-effect transistor as disclosed herein.

In particular embodiments, the system as disclosed herein is configured for forming at least a portion of a field-effect transistor by means of a method as disclosed herein.

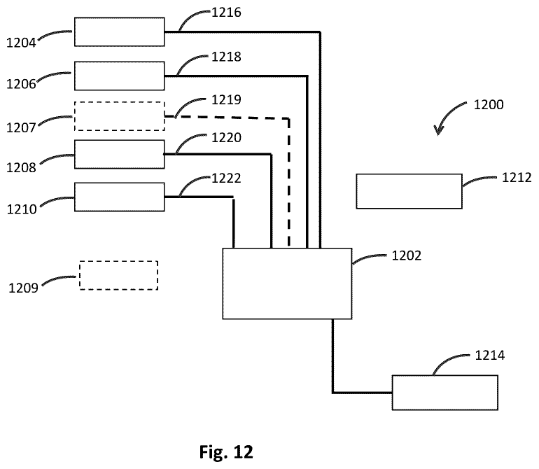

FIG. 12 schematically illustrates a system (1200) in accordance with yet additional exemplary embodiments of the disclosure. The system (1200) can be used to perform a method as described herein and/or form a transistor or device portion as described herein.

In the illustrated example, the system (1200) includes one or more reaction chambers (1202), a boron precursor gas source (1204), a transition metal precursor source (1206), a chalcogenide reactant source (1208), a purge gas source (1210), an exhaust (1212), and a controller (1214).

The reaction chamber (1202) can include any suitable reaction chamber, such as an ALD or CVD reaction chamber. Optionally, the system (1200) comprises further gas sources such as a reactant gas source (1207) and a vacuum power source (1209).

The boron precursor gas source (1204) can include a vessel, and one or more boron precursors as described herein-alone or mixed with one or more carrier (e.g., inert) gases. The transition metal precursor gas source (1206) can include a vessel, and one or more transition metal precursors as described herein-alone or mixed with one or more carrier gases. The chalcogenide reactant gas source (1208) can include a vessel, and one or more nitrogen reactants as described herein-alone or mixed with one or more carrier gases. The purge gas source (1210) can include one or more inert gases such as N₂ or a noble gas, as described herein. The system (1200) can include any suitable number of gas sources. The gas sources (1204)-(1210) can be coupled to reaction chamber (1202) via lines (1216)-(1222), which can each include flow controllers, valves, heaters, and the like. The exhaust (1212) can include one or more vacuum pumps.

The controller (1214) can include electronic circuitry and software to selectively operate valves, manifolds, heaters, pumps, and other components included in the system (1200). Such circuitry and components operate to introduce precursors, reactants, and purge gases from the respective sources (1204)-(1210). The controller (1214) can control timing of gas pulse sequences, temperature of the substrate and/or reaction chamber, pressure within the reaction chamber, and various other operations to provide proper operation of the system (1200).

The controller (1214) can include control software to electrically or pneumatically control valves to control flow of precursors, reactants (e.g., chalcogenide reactants) and purge gases into and out of the reaction chamber (1202). The controller (1214) can include modules such as a software or hardware component, e.g., a FPGA or ASIC, which performs certain tasks. A module can advantageously be configured to reside on the addressable storage medium of the control system and be configured to execute one or more processes.

Other configurations of the system (1200) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (1202). Further, as a schematic representation of a system, many components have been omitted for simplicity of illustration, and such components may include, for example, various valves, manifolds, purifiers, heaters, containers, vents, and/or bypasses.

During operation of the reactor system (1200), substrates, such as semiconductor wafers (not illustrated), are transferred from, e.g., a substrate handling system to reaction chamber (1202). Once substrate(s) are transferred to the reaction chamber (1202), one or more gases from the gas sources (1204)-(1210), such as precursors, reactants, carrier gases, and/or purge gases, are introduced into reaction chamber (1202).

In addition, embodiments of the controller may include a combination of hardware, software, and electronic components or modules that, for purposes of discussion, may be portrayed as if primarily implemented in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits.

The subject matter of the present disclosure includes all novel and nonobvious combinations and subcombinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

What is claimed:

1. A method for the manufacturing of at least a portion of a field-effect transistor (FET), comprising the steps of:
a) providing a substrate into a reaction chamber;
b) executing one or more cycles, a cycle comprising a boron precursor pulse, wherein at least a part of the substrate is contacted with at least one boron precursor by introducing the boron precursor into the reaction chamber, and a reactant gas pulse, wherein at least a part of the substrate is contacted with at least one reactant gas by introducing the reactant gas into the reaction chamber;
wherein, as a result of the cycles, at least one remote dopant layer comprising at least one boron-containing material is formed on the substrate;
wherein the substrate comprises at least one channel layer comprising a channel material that is formed before or after the forming of the remote dopant layer, or a combination thereof; and
wherein the remote dopant layer is configured for the remote doping of the channel material of the channel layer during operation of the field-effect transistor.

2. The method according to claim 1, wherein the boron precursor is represented by the following general formula (I) 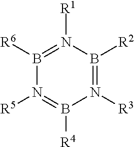
wherein R¹, R², R³, R⁴, R⁵, R⁶ are each independently selected from the group consisting of hydrogen, halogen, alkyl, alkenyl, and alkoxy.

3. The method according to claim 1, wherein R¹, R², R³, R⁴, R⁵, R⁶ are each independently selected from the group consisting of hydrogen, halogen, C₁₋₈alkyl, C₂₋₈alkenyl, and C₁₋₈alkoxy.

4. The method according to claim 1, wherein R¹, R², R³, R⁴, R⁵, R⁶ are each independently selected from the group consisting of hydrogen, halogen, C₁₋₄alkyl, C₂₋₄alkenyl, and C₁₋₄alkoxy.

5. The method according to claim 1, wherein the boron precursor is selected from the group consisting of BF₃, BCl₃, BBr₃, Bl₃, BH₃, B₂H₆, B₄H₁₀, B₅H₉, B₁₀H₁₄, and mixtures thereof.

6. The method according to claim 1, wherein the boron-containing material is selected from the group consisting of boron nitride (BN), boron carbide (BC), boron carbon nitride (BCN), and mixtures thereof.

7. The method according to claim 1, wherein the method is an atomic layer deposition (ALD) method.

8. The method according to claim 1, wherein the remote dopant layer is formed without any intervening vacuum break.

9. The method according to claim 1, wherein the substrate is heated to a temperature of about 80° C. to about 400° C.

10. The method according to claim 1, wherein the channel material comprises a transition metal dichalcogenide selected from the group consisting of MoS₂, MoSe₂, MoTe₂, WS₂, WSe₂, WTe₂, NbS₂, NbSe₂, NbTe₂, VS₂, VSe₂, VTe₂, ReS₂, ReSe₂, ReTe₂, TaS₂, TaSe₂, TaTe₂, and mixtures thereof.

11. The method according to claim 1, wherein the channel material comprises graphene.

12. The method according to claim 1, wherein the remote dopant layer has an average thickness of between 0.05 nm and 2.0 nm.

13. The method according to claim 1, wherein the at least one channel layer is formed by:
A) providing the substrate to the reaction chamber;
B) executing one or more cycles, a cycle comprising
i. a transition metal precursor pulse, wherein at least a part of the substrate is contacted with at least one transition metal precursor by introducing the transition metal precursor into the reaction chamber;
ii. a chalcogenide reactant pulse, wherein at least a part of the substrate is contacted with at least one chalcogenide reactant by introducing the chalcogenide reactant into the reaction chamber; and
wherein, as a result of the cycles, the at least one channel layer comprising the channel material is formed on at least one of the substrate and the remote dopant layer.

14. The method according to claim 13, wherein the at least one channel layer and the remote dopant layer are formed in the same reaction chamber without any intervening vacuum break.

15. The method according to claim 13, wherein the transition metal precursor comprises a transition metal in oxidation state +4.

16. The method according to claim 13, wherein the transition metal precursor comprises a transition metal element chosen from the group including at least one of Mo, W, Nb, V, Re, and Ta.

17. The method according to claim 13, wherein the chalcogenide reactant is selected from the group consisting of H₂S, H₂S plasma, H₂Se, Et₂Se, Se₂(Si(i-Pr)₂)₂, [(CH₃)₃Si]>Se, [(CH₃)₃Si]Te and Te[Oi-Pr]₄.

18. A system for the manufacturing of at least a portion of a field-effect transistor comprising:
a reaction chamber constructed and arranged to hold a substrate;
a boron precursor vessel constructed and arranged to contain and evaporate at least one boron precursor;
a transition metal precursor vessel constructed and arranged to contain and evaporate at least one transition metal precursor;
a chalcogenide reactant vessel constructed and arranged to contain and evaporate at least one chalcogenide reactant;
a controller, operatively connected to the boron precursor vessel, the transition metal precursor vessel, and the chalcogenide reactant vessel;
wherein the controller is configured to control the introduction of the boron precursor, the transition metal precursor, and the chalcogenide reactant into the reaction chamber during one or more cycles; and,
wherein, as a result of the cycles, at least one remote dopant layer comprising a boron-containing material and at least one channel layer comprising a channel material are formed on the substrate; and wherein the remote dopant layer is configured for remote doping of the channel material comprised in the channel layer during operation of the field-effect transistor.

19. The system according to claim 18, wherein the system is configured for forming at least a portion of a field-effect transistor.
